(19) United States
(12) Patent Application Publication
(10) Pub. No.: US 2008/0054315 A1
(43) Pub. Date: Mar. 6, 2008

(54) METHOD FOR MANUFACTURING SEMICONDUCTOR DEVICE BY USING TWO STEP POCKET IMPLANT PROCESS

(76) Inventor: Ji-Ho Hong, Gyeonggi-do (KR)

Correspondence Address: SHERR & NOURSE, PLLC, 620 HERNDON PARKWAY, SUITE 200, HERNDON, VA, 20170, US

(21) Appl. No.: 11/846,954

(22) Filed: Aug. 29, 2007

(30) Foreign Application Priority Data
Sep. 1, 2006 (KR) 10-2006-0084162

(51) Int. Cl. H01L 21/336; H01L 29/78

(52) U.S. Cl. 257/288; 438/306; 257/E29.255; 257/E21.409

(57) ABSTRACT

Embodiments relate to a method for manufacturing a semiconductor device by forming a gate pattern over a semiconductor substrate. A material, which has a higher atomic weight than that of a pocket implant dopant, is implanted at an angle or tilt into the respective pocket implant areas at both sides of the gate pattern. The pocket implant dopant is then implanted into the respective pocket implant areas at both sides of the gate pattern.

The present application claims priority under 35 U.S.C. 119 to Korean Patent Application No. 10-2006-0084162, filed on Sep. 1, 2006, which is hereby incorporated by reference in its entirety.

### BACKGROUND

When reducing the size of semiconductor devices, it is essential to effectively suppress a short channel effect. To this end, a pocket implant technology may be used. As shown in FIG. 1, the pocket implant includes a pocket implant area 7 beneath a channel 4. The pocket implant area 7 is formed by implanting impurities in a tilted orientation along the sides of a source 2 and a drain 3. For reference, the semiconductor device may include for example the source 2, the drain 3, the channel 4, a gate electrode 5 controlling the channel, and a gate oxide film 6.

Since reducing the size of devices tends to continuously shorten the channel of the transistor, the channel beneath a gate pattern may overlap a pocket implant area. The overlap effect may reduce carrier mobility in the semiconductor device and increase the doping concentration in the channel area. Increased doping concentration may cause the threshold voltage to increase. As the critical dimension (CD) of the gate pattern gets small, a high dose implant may be applied to the pocket implant process to suppress the channel effect. The overlap phenomenon of the pocket implant area may be further exacerbated.

### SUMMARY

Embodiments relate to a method for manufacturing a semiconductor device, and more particularly to a method for manufacturing a semiconductor device by using two step pocket implant process capable of preventing an overlap phenomenon of a pocket implant.

Embodiments relate to a method for manufacturing a semiconductor device by forming a gate pattern over a semiconductor substrate. A material, which has a higher atomic weight than that of a pocket implant dopant, is implanted at an angle or tilt into the respective pocket implant areas at both sides of the gate pattern. The pocket implant dopant is then implanted into the respective pocket implant areas at both sides of the gate pattern.

In embodiments, the material with higher atomic weight than that of the pocket implant dopant is Ge. The pocket implant dopant may be BF₂ for NMOS semiconductor devices and As for PMOS semiconductor devices.

An apparatus according to embodiments therefore includes a semiconductor substrate defining at least one gate region, barrier regions on two sides of the gate region, and pocket implant areas within each of the barrier regions. A gate is formed over the gate region. A first impurity material is implanted into the barrier regions. A second impurity material implanted into the pocket implant areas. The first impurity material has a higher atomic weight than said second impurity material. The pocket implant areas are smaller than, and completely enveloped by, the barrier regions. The structure may be part of a PMOS or NMOS transistor.

### DRAWINGS

FIG. 1 is a cross-sectional view of a semiconductor device for explaining a pocket implant of a related art.

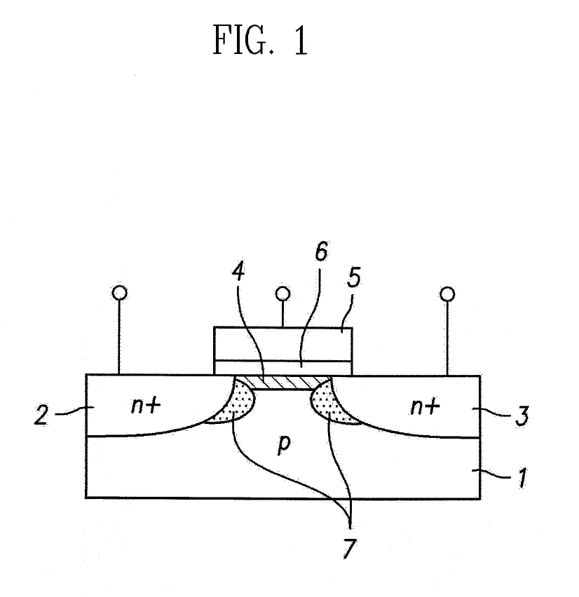

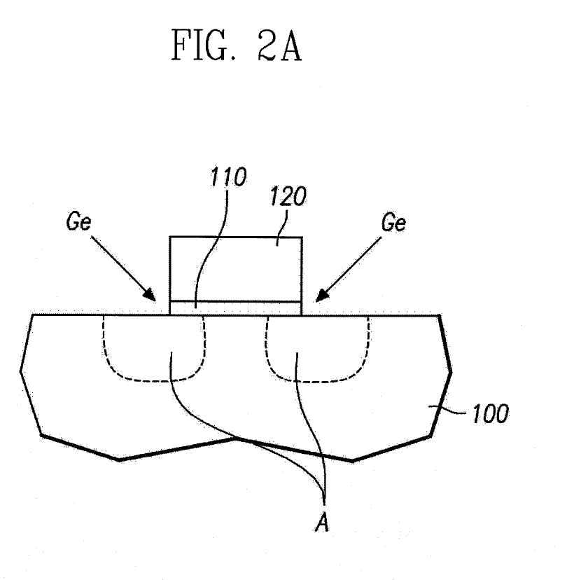

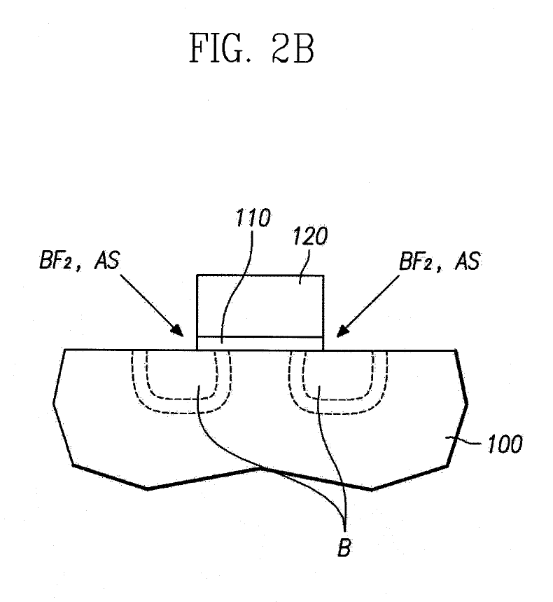

Example FIGS. 2a and 2b are cross-sectional views showing a cross section of a process performing a two step pocket implant according to embodiments.

### DESCRIPTION

Hereinafter, embodiments of a method for manufacturing a semiconductor device using a two step pocket implant according to embodiments will be described with reference to the accompanying drawings.

Example FIG. 2a shows a first step cross section and Example FIG. 2b shows a second step cross section in the two step pocket implant process according to embodiments.

First, as shown in example FIG. 2a, a first step in a two step pocket implant process is performed begins with an insulating layer 110 and a gate pattern 120 over a semiconductor substrate 100. A relatively heavy material, for example, Ge, etc., may be implanted into both sides of the gate pattern 120 at a predetermined tilt angle. The implanted material has a larger atomic weight than a pocket implant dopant material. The relatively heavy material may help prevent a pocket implant dopant from being laterally diffused on a semiconductor substrate 100.

Barrier area A, shown in example FIG. 2a, is formed by the implanted material with a larger atomic weight than that of the pocket implant dopant. It may be implanted at a predetermined tilt angle. The barrier area A may be amorphized so that the overlap effect may be minimized in a thermal process performed after the pocket implant.

Next, a second step may be performed in the two step pocket implant process according to embodiments. The second step in the two step implant process implants dopant at a tilt or angle into both sides of the gate pattern 120. The dopant may be BF₂ for NMOS devices and As for PMOS devices.

As shown in example FIG. 2b, a pocket implant area B is formed within the barrier area A. The lateral diffusion of the pocket implant dopant can effectively be suppressed by means of the barrier area A which may be formed by a Ge implant.

Even though the critical dimension of the gate pattern is shortened, the performance of the semiconductor device may be maintained. The overlap effect is complemented so that carrier mobility of the semiconductor device may be improved, and the effectiveness of the pocket implant may be improved.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a gate pattern having at least two sides over a semiconductor substrate;
implanting a material with higher atomic weight than that of a pocket implant dopant into areas at both sides of the gate pattern; and
implanting the pocket implant dopant into the respective pocket implant areas along two sides of the gate pattern.

2. The method according to claim 1, wherein the material with higher atomic weight than that of the pocket implant dopant is Ge.

3. The method according to claim 1, wherein the pocket implant dopant is BF₂ for forming an NMOS type device.

4. The method according to claim 1, wherein the pocket implant dopant is As for forming a PMOS type device.

5. A method comprising:
preparing a semiconductor substrate, and defining therein at least one gate region, barrier regions on two sides of said at least one gate region, and pocket implant areas within each of said barrier regions;
forming a gate over said gate region;
implanting a first impurity material into said barrier regions; and
implanting a second impurity material into said pocket implant areas, wherein said first impurity material has a higher atomic weight than said second impurity material.

6. The method of claim 5, wherein said first impurity material is Germanium.

7. The method of claim 5, wherein said second impurity material is BF₂

8. The method of claim 5, wherein said second impurity material is As.

9. The method of claim 5, wherein said pocket implant areas are smaller than, and completely enveloped by, said barrier regions.

10. The method of claim 5, wherein said barrier region is amorphized.

11. The method of claim 7, comprising forming an NMOS transistor.

12. The method of claim 8, comprising forming an PMOS transistor.

13. An apparatus comprising:
a semiconductor substrate defining therein at least one gate region, barrier regions on two sides of said at least one gate region, and pocket implant areas within each of said barrier regions;
a gate formed over said gate region;
a first impurity material implanted into said barrier regions;
a second impurity material implanted into said pocket implant areas, wherein said first impurity material has a higher atomic weight than said second impurity material.

14. The method of claim 13, wherein said first impurity material is Germanium.

15. The method of claim 13, wherein said second impurity material is BF₂

16. The method of claim 13, wherein said second impurity material is As.

17. The method of claim 13, wherein said pocket implant areas are smaller than, and completely enveloped by, said barrier regions.

18. The method of claim 13, wherein said barrier region is amorphized.

19. The method of claim 15, comprising forming an NMOS transistor.

20. The method of claim 16, comprising forming an PMOS transistor.
